(19) United States
(12) Patent Application Publication
(10) Pub. No.: US 2013/0322481 A1
(43) Pub. Date: Dec. 5, 2013

(54) LASER DIODES INCLUDING SUBSTRATES HAVING SEMIPOLAR SURFACE PLANE ORIENTATIONS AND NONPOLAR CLEAVED FACETS

(71) Applicants: Rajaram Bhat, Painted Post, NY (US); Dmitry Sergeevich Sizov, Corning, NY (US); Chung-En Zah, Holmdel, NJ (US)

(72) Inventors: Rajaram Bhat, Painted Post, NY (US); Dmitry Sergeevich Sizov, Corning, NY (US); Chung-En Zah, Holmdel, NJ (US)

(21) Appl. No.: 13/485,385

(22) Filed: May 31, 2012

(51) Int. Cl. H01S 5/34; H01L 21/20

(52) U.S. Cl. 372/45.012; 438/31; 257/E21.09

(57) ABSTRACT

Laser diodes and methods of fabricating laser diodes are disclosed. A laser diode includes a substrate including (Al,In)GaN, an n-side cladding layer including (Al,In)GaN having an n-type conductivity, an n-side waveguide layer including (Al,In)GaN having an n-type conductivity, an active region, a p-side waveguide layer including (Al,In)GaN having a p-type conductivity, a p-side cladding layer including (Al,In)GaN having a p-type conductivity, and a laser cavity formed by cleaved facets. The substrate includes a crystal structure having a surface plane orientation within about 10 degrees of a 20 2̅3 or a 20 2̅3̅ crystallographic plane orientation. The laser cavity is formed by cleaved facets that have an orientation corresponding to a nonpolar plane of the crystal structure of the substrate.

### TECHNICAL FIELD

The present disclosure relates to semiconductor lasers and, more specifically, to laser diodes and substrate surface plane orientations thereof.

### BACKGROUND

Laser diodes typically include a number of layers formed on a substrate and a laser cavity formed by cleaved facets. The present disclosure is directed to laser diodes having particular substrate surface plane orientations and cleaved facet orientations.

### SUMMARY

The inventors have recognized that semiconductor laser diodes with low quantum confinement stark effect (QCSE), high differential optical gain (DOG), and easily cleaved facets are desirable. Laser diodes with low QCSE and high DOG may possess a number of desirable features, including low threshold current density and higher wall plug efficiency, particularly in the green wavelength range. Laser diodes with easily cleaved facets may be desirable because such laser diodes may be formed with a high manufacturing yield compared to laser diodes with facets that are more difficult to cleave.

However, the inventors have recognized that it is difficult to fabricate laser diodes with low QCSE, high DOG, and easily cleaved facets. For example, laser diodes including substrates having certain surface plane orientations that permit facets to be easily cleaved (e.g., a laser diode with a substrate having a c-plane surface plane orientation) may have high QCSE that may lower DOG, thereby degrading laser performance. Thus, it may be desirable to design alternative laser diodes with substrate surface plane orientations that result in lower QCSE and higher DOG.

However, the inventors have recognized that laser diodes with certain surface plane orientations that may have lower QCSE and higher DOG may have a laser cavity formed by facets that are not easily cleaved. In particular, in such a laser diode, a laser stripe may be configured to extend along a high gain semipolar direction. A laser cavity may be formed by facets along high index planes that are perpendicular to the direction in which the laser stripe extends. Cleaving laser facets along high index planes may be difficult and may result in a low yield of lasers with undesirable facets because the facet quality may be poor. Further, in the context of laser diodes emitting photons in the green wavelength range, the inventors have recognized that laser diodes with some surface plane orientations having high DOG in a direction perpendicular to a low index plane may not be suitable for growing InGaN quantum wells in the active region for emitting photons in the green wavelength range.

Given the challenge of designing laser diodes that result in low QCSE, high DOG, and easily cleaved facets, the inventors have recognized the potential benefits of laser diodes having substrates with particular surface plane orientations and cleaved facet orientations that achieve low QCSE, high DOG (particularly in the blue-green and green spectral ranges), and easily cleaved facets.

In one embodiment, a laser diode includes a substrate including (Al,In)GaN, an n-side cladding layer including (Al,In)GaN having an n-type conductivity, an n-side waveguide layer including (Al,In)GaN having an n-type conductivity, an active region, a p-side waveguide layer including (Al,In)GaN having a p-type conductivity, a p-side cladding layer including (Al,In)GaN having a p-type conductivity, and a laser cavity formed by cleaved facets. The active region is interposed between the n-side cladding layer and the p-side cladding layer and extends substantially parallel to the n-side cladding layer and the p-side cladding layer. The p-side waveguide layer is interposed between the active region and the p-side cladding layer. The n-side waveguide layer is interposed between the active region and the n-side cladding layer. The n-side cladding layer is interposed between the n-side waveguide layer and the substrate. The active region includes one or more InGaN quantum wells producing electrically-pumped stimulated emission of photons. The emission of photons is guided along an axis of propagation by the n-side waveguide layer and the p-side waveguide layer. The propagation along the axis of propagation is promoted by the n-side cladding layer and the p-side cladding layer. The substrate includes a crystal structure having a surface plane orientation within about 10 degrees of a 20 2̅3 or a 20 2̅3̅ crystallographic plane orientation. The laser cavity is formed by cleaved facets that have an orientation corresponding to a nonpolar plane of the crystal structure of the substrate.

In another embodiment, a method of fabricating a laser diode includes growing an epitaxial structure. The epitaxial structure includes a substrate including (Al,In)GaN, an n-side cladding layer including (Al,In)GaN having an n-type conductivity, an n-side waveguide layer including (Al,In)GaN having an n-type conductivity, an active region, a p-side waveguide layer including (Al,In)GaN having a p-type conductivity, and a p-side cladding layer including (Al,In)GaN having a p-type conductivity. The active region is interposed between the n-side cladding layer and the p-side cladding layer and extends substantially parallel to the n-side cladding layer and the p-side cladding layer. The p-side waveguide layer is interposed between the active region and the p-side cladding layer. The n-side waveguide layer is interposed between the active region and the n-side cladding layer. The n-side cladding layer is interposed between the n-side waveguide layer and the substrate. The active region includes one or more InGaN quantum wells producing electrically-pumped stimulated emission of photons. The emission of photons is guided along an axis of propagation by the n-side waveguide layer and the p-side waveguide layer. The propagation along the axis of propagation is promoted by the n-side cladding layer and the p-side cladding layer. The substrate includes a crystal structure having a surface plane orientation within about 10 degrees of a 20 2̅3 or a 20 2̅3̅ crystallographic plane orientation. The method further includes cleaving the epitaxial structure to form facets that form a laser cavity. The cleaved facets have an orientation corresponding to a nonpolar plane of the crystal structure of the substrate.

Additional embodiments are described.

### BRIEF DESCRIPTION OF THE DRAWINGS

The following detailed description of specific embodiments of the present disclosure can be best understood when read in conjunction with the following drawings, where like structure is indicated with like reference numerals and in which:

FIG. 1A schematically depicts a cross-sectional side view of a laser diode, according to one or more embodiments shown and described herein;

FIG. 1B schematically depicts an inset view of the active region of the laser diode shown in FIG. 1A, according to one or more embodiments shown and described herein;

FIG. 2 schematically depicts a hexagonal crystal structure used to define a coordinate system to describe the orientation of various aspects of the laser diode described herein;

FIG. 3 is a graph of photoluminescence intensity with a projected c direction E-vector component and a nonpolar E-vector component as a function of wavelength for a laser diode emitting light in the green wavelength range at a high pump power density, according to one or more embodiments shown and described herein;

FIG. 4 is a graph of photoluminescence intensity with a projected c direction E-vector component and a nonpolar E-vector component as a function of wavelength for a laser diode emitting light in the green wavelength range at a low pump power density, according to one or more embodiments shown and described herein;

FIG. 5 is a graph of photoluminescence intensity with a projected c direction E-vector component and a nonpolar E-vector component as a function of wavelength for a laser diode emitting light in the blue-green wavelength range at a high pump power density, according to one or more embodiments shown and described herein; and

FIG. 6 is a graph of photoluminescence intensity with a projected c direction E-vector component and a nonpolar E-vector component as a function of wavelength for a laser diode emitting light in the blue-green wavelength range at a low pump power density, according to one or more embodiments shown and described herein.

### DETAILED DESCRIPTION

Features and advantages of the various embodiments of the present disclosure will now be described. However, the present disclosure should not be construed as limited to the embodiments set forth herein.

As used herein, the term “Group III nitride-based” with respect to a device or a device layer means that the device or the device layer is fabricated on a substrate of a Group III element nitride. Group III element nitride materials include, but are not limited to binary gallium nitride, ternary alloys such as aluminum gallium nitride (AlGaN) and indium gallium nitride (InGaN), and quaternary alloys such as aluminum indium gallium nitride (AlInGaN).

Parentheses in formulas representing the various Group III nitrides denote optional elements, whereas elements outside of parentheses are to be regarded as required within a given alloy. For example, the notation (Al)InGaN corresponds to an alloy comprising InGaN, in which aluminum or, more specifically, AlN, is optional. As such, “(Al)InGaN” is equivalent to “InGaN or AlInGaN.” Likewise, the notation (Al,In)GaN corresponds to an alloy comprising GaN, in which both aluminum (as AlN) and indium (as InN) are optional as alloy elements. As such “(Al,In)GaN” is equivalent to “GaN, AlGaN, InGaN, or AlInGaN.”

When used without further qualification as to composition or stoichiometry, formulas such as AlGaN or AlInGaN are to be understood as encompassing the entire available compositional range, as though the formulas were written in the form AlₓGa₁₋ₓN or AlₓIn_{y}Ga_{1-x-y}N respectively, where 0<x<1 and 0<y<1, such that x+y<1. Similarly, (Al)InGaN is to be understood as equivalent to AlₓIn_{y}Ga_{1-x-y}N, where 0≦x<1 and 0<y<1, such that x+y<1. The formula (Al,In)GaN is to be understood as equivalent to AlₓIn_{y}Ga_{1-x-y}N, where 0≦x<1 and 0≦y<1, such that x+y<1. As will be evident from these compositional ranges, the values attached to the subscripts corresponding to optional elements each include zero as possibilities, whereas the values for required elements each do not include zero as possibilities. Any given layer described according to a generic formula (e.g., AlGaN or (Al,In)GaN) or a range formula (e.g., AlₓGa₁₋ₓN or AlₓIn_{y}Ga_{1-x-y}N) may be a bulk layer having a specific and essentially uniform composition according to the generic formula or range formula, a superlattice having an average composition according to the generic formula or range formula, a periodic structure having an average composition according to the generic formula or range formula, or a compositionally gradient structure comprising a plurality of zones having an average composition according to the generic formula or range formula.

With particular regard to the Group III elements aluminum, indium, and gallium, any Group III element not included in a formula of a Group III nitride is presumed to be not present at higher than an a natural impurity level in the Group III nitride described by the formula.

Except where explicitly stated to the contrary, it will be understood further that each of the nitride alloys may be doped with one or more dopants such as, for example, magnesium (a p-type dopant with respect to Group III nitride semiconductors) or silicon (an n-type dopant with respect to Group III nitride semiconductor). The one or more dopants do not appear in the formulas for the various alloys but are recited separately, such as by reciting that a given alloy is “n-doped” or “p-doped,” for example. Unless positively recited as undoped, n-doped, p-doped, or any combination of two of these, each nitride alloy may be undoped, n-doped, or p-doped.

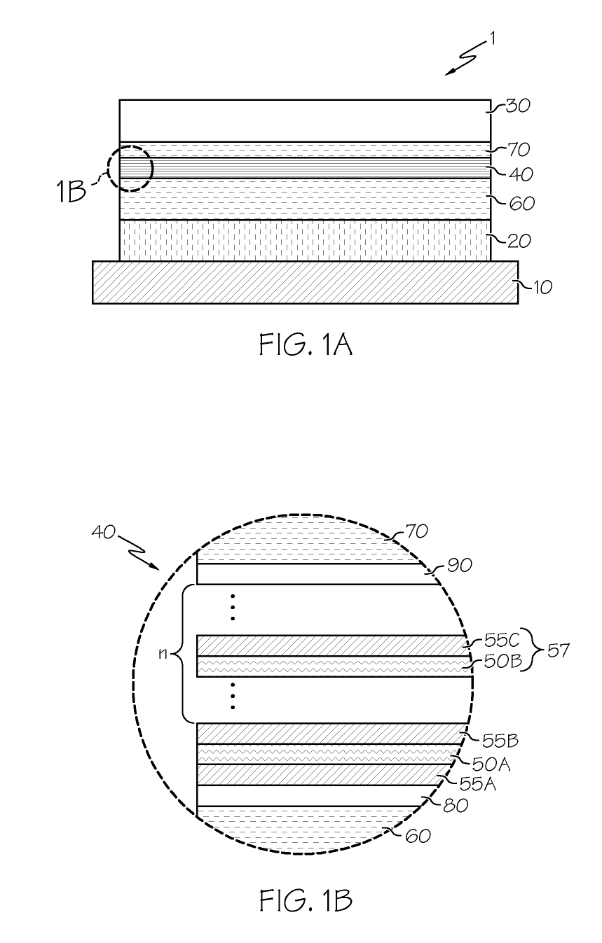

The laser diode 1 illustrated in FIG. 1A comprises a substrate 10, an n-side cladding layer 20, an n-side waveguide layer 60, an active region 40, a p-side waveguide layer 70, and a p-side cladding layer 30. The active region 40 is interposed between the n-side cladding layer 20 and the p-side cladding layer 30 and extends substantially parallel to the n-side cladding layer 20 and the p-side cladding layer 30. The p-side waveguide layer 70 is interposed between the active region 40 and the p-side cladding layer 30. The n-side waveguide layer 60 is interposed between the active region 40 and the n-side cladding layer 20. The n-side cladding layer 20 is interposed between the n-side waveguide layer 60 and the substrate.

The n-side cladding layer 20 comprises (Al,In)GaN having an n-type conductivity. The n-type conductivity of the n-side cladding layer 20 may be realized in a number of ways, including, but not limited to, gradient polarization, doping with an n-type dopant, or a combination of gradient polarization and doping with an n-type dopant. In some embodiments, it may be preferred that the n-side cladding layer 20 be a layer of n-doped GaN. In other embodiments, it may be preferred that the n-side cladding layer 20 be a layer of n-doped AlInGaN. In one embodiment, the n-side cladding layer 20 may be n-doped with silicon. In other embodiments, the n-side cladding layer 20 may be doped with an n-type dopant other than, or in addition to, silicon.

The n-side cladding layer 20 may be a single layer or may include multiple (Al,In)GaN sublayers. In embodiments that include multiple (Al,In)GaN sublayers, the concentration of Al and In in a first sublayer may differ from the concentration of Al and In in a second sublayer.

The n-side waveguide layer 60 comprises (Al,In)GaN having an n-type conductivity. The n-type conductivity of the n-side waveguide layer 60 may be realized in a number of ways, including, but not limited to, gradient polarization, doping with an n-type dopant, or a combination of gradient polarization and doping with an n-type dopant. In some embodiments, it may be preferred that the n-side waveguide layer 60 be a layer of n-doped InGaN. In one embodiment, the n-side waveguide layer 60 may be n-doped with silicon. In other embodiments, the n-side waveguide layer 60 may be doped with an n-type dopant other than, or in addition to, silicon.

The n-side waveguide layer 60 may be a single layer or may include multiple (Al,In)GaN sublayers. In embodiments that include multiple (Al,In)GaN sublayers, the concentration of Al and In in a first sublayer may differ from the concentration of Al and In in a second sublayer.

The active region 40 comprises one or more InGaN quantum wells that produce electrically-pumped stimulated emission of photons. In one embodiment, the emission wavelength may be from about 470 nm to about 550 nm. The emission of photons from the active region 40 may be guided along an axis of propagation by the n-side waveguide layer 60 and the p-side waveguide layer 70. In one embodiment, the emission of photons from the active region 40 may be guided along an axis of propagation by a ridge waveguide. Further, the propagation of the photons along the axis of propagation may be promoted by the n-side cladding layer 20 and the p-side cladding layer 30. In some embodiments, each InGaN quantum well may be interposed between two (Al,In)GaN quantum well barriers.

The layer structure of the active region 40 of the laser diode 1, which includes multiple InGaN quantum wells interposed between (Al,In)GaN quantum well barriers, is shown in greater detail in FIG. 1B. The active region 40 in FIG. 1B is shown as an exploded view to illustrate optional repetition of the quantum well layers. It will be understood that all layers of the active region 40 are stacked on each other as a continuous multilayer, but that the continuous multilayer may include additional layers interposed between the layers. The additional layers may comprise spacers, for example, which may be present to optimize the performance of the active region 40 but are not necessary for the active region 40 to function. In general, a quantum well 50A is interposed between a first quantum well barrier 55A and a second quantum well barrier 55B. In one embodiment, each quantum well 50A, 50B may be from about 1 nm to about 10 nm thick and may be a single layer or multiple layers. Each quantum well 50A, 50B may be one or more layers of InGaN. The InGaN of the quantum wells 50A, 50B may have an InN molar concentration from about 20% to about 80%, for example. Similarly, the quantum well barriers 55A, 55B, 55C individually may be single layers or multiple layers. The quantum well barriers 55A, 55B, 55C each may be layers of AlInGaN and may have thicknesses from about 1 nm to about 30 nm, for example

The active region 40 may comprise one quantum well or may comprise multiple quantum wells. In FIG. 1B, a repeat unit 57 is shown as an additional quantum well 50B and an additional quantum well barrier layer 55C, such that when the repeat unit 57 is stacked onto an existing quantum well barrier, such as onto the second quantum well barrier 55B, the top barrier layer of a first quantum well (here, second quantum well barrier 55B) becomes also the bottom barrier layer of the additional quantum well 50B. The active region 40 may comprise a number n of the repeat units 57, where n may be zero in a single-well active region or may be an integer from 1 to 20, from 1 to 10, from 1 to 5, or from 1 to 3 for multiple-well active regions.

In some embodiments, the laser diode 1 may further comprise a hole-blocking layer 80, an electron-blocking layer 90, or both. When present, the hole-blocking layer 80 may be interposed between the active region 40 and the n-side waveguide layer 60. When present, the electron-blocking layer 90 may be interposed between the active region 40 and the p-side waveguide layer 70. In an alternative embodiment, the electron-blocking layer may be interposed between the p-side waveguide layer and the p-side cladding layer. While the embodiment depicted in FIG. 1B has a hole-blocking layer 80 and an electron-blocking layer 90, other embodiments may not include a hole-blocking layer 80 or an electron-blocking layer 90. In one embodiment, the hole-blocking layer 80 comprises (Al,In)GaN. In one particular embodiment, the hole-blocking layer 80 comprises Al(In)GaN.

Referring once again to FIG. 1A, the p-side waveguide layer 70 comprises (Al,In)GaN having a p-type conductivity. The p-type conductivity of the p-side waveguide layer 70 may be realized in a number of ways, including, but not limited to, gradient polarization, doping with a p-type dopant, or a combination of gradient polarization and doping with a p-type dopant. In some embodiments, it may be preferred that the p-side waveguide layer 70 be a layer of p-doped InGaN.

The p-side waveguide layer 70 may be a single layer or may include multiple (Al,In)GaN sublayers. In embodiments that include multiple (Al,In)GaN sublayers, the concentration of Al and In in a first sublayer may differ from the concentration of Al and In in a second sublayer.

The p-side cladding layer 30 comprises (Al,In)GaN having a p-type conductivity. The p-type conductivity of the p-side cladding layer 30 may be realized in a number of ways, including, but not limited to, gradient polarization, doping with a p-type dopant, or a combination of gradient polarization and doping with a p-type dopant.

The p-side cladding layer 30 may be a single layer or may include multiple (Al,In)GaN sublayers. In embodiments that include multiple (Al,In)GaN sublayers, the concentration of Al and In in a first sublayer may differ from the concentration of Al and In in a second sublayer.

In one embodiment, at least one of the n-side cladding layer 20 and the p-side cladding layer 30 includes Al(In)GaN. In another embodiment, at least one of the n-side waveguide layer 60 and the p-side waveguide layer 70 includes (Al)InGaN. In yet another embodiment, at least one of the n-side cladding layer 20 and the p-side cladding layer 30 includes Al(In)GaN and at least one of the n-side waveguide layer 60 and the p-side waveguide layer 70 includes (Al)InGaN. In still another embodiment, at least one of the n-side cladding layer 20 and the p-side cladding layer 30 includes Al(In)GaN with an Al concentration of less than about 50% and at least one of the n-side waveguide layer 60 and the p-side waveguide layer 70 includes (Al)InGaN with an In concentration of less than about 50%.

In one embodiment, at least one of the n-side waveguide layer 60 and the p-side cladding layer 30 may be partially or fully relaxed via formation of misfit dislocations positioned at least 20 nm from at least one of the one or more InGaN quantum wells of the active region 40.

The substrate 10 comprises (Al,In)GaN. The substrate 10 may have an n-type conductivity or a p-type conductivity. The cladding layer having the same conductivity type as the substrate 10 is disposed closer to the substrate than the cladding layer having the conductivity type opposite that of the substrate 10. In the embodiments described herein, it is preferred that the substrate 10 be an n-type semiconductor material, that the n-side cladding layer 20 be interposed between the n-side waveguide layer 60 and the substrate 10, and that the p-side cladding layer 30 be disposed above the n-side cladding layer 20. Examples of materials suitable as substrate 10 include, but are not limited to, free-standing Group III nitride materials such as GaN, AlN, InN, AlGaN, GaInN, or AlInGaN. In preferred embodiments, the substrate may be free-standing GaN. Though an n-type substrate is preferred, it is fully contemplated in another embodiment that a p-type substrate may be used, such that the p-side cladding layer 30 would be interposed between the p-side waveguide layer 70 and the substrate 10 and such that the n-side cladding layer 20 would be disposed above the p-side cladding layer 30.

The laser diode 1 may further comprise additional layers or spacers between any two of the layers depicted in FIG. 1A. As non-limiting examples, one or more GaN spacers may be interposed between the p-side waveguide layer 70 and the p-side cladding layer 30, or between the n-side waveguide layer 60 and the n-side cladding layer 20. The laser diode 1 may further comprise contact layers and/or interconnections for establishing electrical continuity between the n-side cladding layer 20 and the p-side cladding layer 30 through a power source configured to introduce electrons into the n-side cladding layer 20. For example, a first contact layer may be formed on a back side of the substrate 10 opposite the n-side cladding layer 20, and a second contact layer may be formed on the p-side cladding layer 30. Alternatively, the first contact layer may be formed on a portion of the substrate not covered by the n-side cladding layer 20.

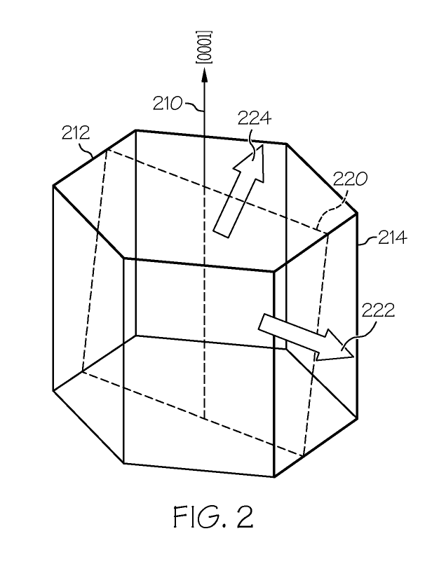

Referring now to FIG. 2, a hexagonal crystal structure is depicted. A coordinate system defined with respect to the hexagonal crystal structure of FIG. 2 will be utilized to describe the surface plane orientation of the substrate 10 and the orientation of the cleaved facets of the laser diode 1. The crystal structure includes a c-axis 210, which extends in the [0001] direction (commonly referred to as the “c direction”). The crystallographic plane that extends perpendicular to the c-axis 210 is referred to as the c-plane 212. A crystallographic plane that is perpendicular to the c-plane 212 is defined to be a “nonpolar plane” (e.g., nonpolar plane 214). A crystallographic plane that is tilted away from the c-axis 210 by less than 90 degrees is defined to be a “semipolar plane” (e.g., semipolar plane 220). The direction that extends parallel to the semipolar plane 220 and perpendicular to the c-axis 210 is defined as extending in the “nonpolar direction” 222 of the semipolar plane 220. The direction that extends parallel to the semipolar plane 220 and perpendicular to the nonpolar direction 222 is defined as extending in the “projected c direction” 224 of the semipolar plane 220.

In one embodiment, the laser diode 1 has a substrate 10 with a crystal structure having a surface plane orientation within about 10 degrees of a 20 2̅3 or a 20 2̅3̅ crystallographic plane orientation. In one embodiment, the substrate 10 has a surface plane orientation of about 20 2̅3. In another embodiment, the substrate 10 has a surface plane orientation of about 20 2̅3̅. In other embodiments, the substrate 10 may have a crystal structure having a semipolar surface plane orientation other than 20 2̅3 or 20 2̅3̅.

The laser diode 1 includes a laser cavity formed by cleaved facets. The cleaved facets have an orientation corresponding to a nonpolar plane of the crystal structure of the substrate 10. In one embodiment, the cleaved facets may have a 11 2̅0 crystallographic plane orientation. The axis of propagation along which the photons emitted by the laser diode 1 are guided is typically perpendicular to the cleaved facets. Accordingly, in an embodiment in which the laser diode 1 has cleaved facets having a 11 2̅0 crystallographic plane orientation, the axis of propagation along which the photons emitted by the laser diode 1 are guided may extend in a direction within about 10 degrees of the <11 2̅0> direction. In one particular embodiment in which the laser diode 1 has cleaved facets having a 11 2̅0 crystallographic plane orientation, the axis of propagation along which the photons emitted by the laser diode 1 are guided may extend in approximately the <11 2̅0> direction.

In one embodiment, the laser diode 1 has a substrate 10 having a surface plane orientation within about 10 degrees of a 20 2̅3 or a 20 2̅3̅ crystallographic plane orientation, a laser cavity with cleaved facets having a 11 2̅0 crystallographic plane orientation and an axis of propagation along which the photons are guided that extends in a direction within about 10 degrees of the <11 2̅0> direction. In another embodiment, the laser diode 1 has a substrate 10 having a surface plane orientation within about 10 degrees of a 20 2̅3 or a 20 2̅3̅ crystallographic plane orientation, a laser cavity with cleaved facets having a 11 2̅0 crystallographic plane orientation and an axis of propagation along which the photons are guided that extends in approximately the <11 2̅0> direction.

In one embodiment, the laser diode 1 has a substrate 10 having a surface plane orientation of about 20 2̅3, a laser cavity with cleaved facets having a 11 2̅0 crystallographic plane orientation and an axis of propagation along which the photons are guided that extends in a direction within about 10 degrees of the <11 2̅0> direction. In another embodiment, the laser diode 1 has a substrate 10 having a surface plane orientation of about 20 2̅3, a laser cavity with cleaved facets having a 11 2̅0 crystallographic plane orientation and an axis of propagation along which the photons are guided that extends in approximately the <11 2̅0> direction.

In one embodiment, the laser diode 1 has a substrate 10 having a surface plane orientation of about 20 2̅3̅, a laser cavity with cleaved facets having a 11 2̅0 crystallographic plane orientation and an axis of propagation along which the photons are guided that extends in a direction within about 10 degrees of the <11 2̅0> direction. In another embodiment, the laser diode 1 has a substrate 10 having a surface plane orientation of about 20 2̅3̅, a laser cavity with cleaved facets having a 11 2̅0 crystallographic plane orientation and an axis of propagation along which the photons are guided that extends in approximately the <11 2̅0> direction.

A laser diode 1 having a substrate 10 with a crystal structure having a surface plane orientation within about 10 degrees of a 20 2̅3 or a 20 2̅3̅ crystallographic plane orientation typically has sufficient indium concentration in the InGaN of the quantum wells to produce green light, unlike other potential semipolar surface plane orientations of the substrate 10. Further, a laser diode 1 having a substrate 10 with a crystal structure having a surface plane orientation with about 10 degrees of a 20 2̅3 or a 20 2̅3̅ crystallographic plane orientation typically exhibits high optical gain and reduced QCSE for photons propagating in the nonpolar direction, when compared to laser diodes having substrates with other surface plane orientations. Because laser facets are typically formed by cleaving along a plane perpendicular to the propagation direction of the photons, laser facets can be easily cleaved along a low index nonpolar plane when the substrate 10 of the laser diode 1 has a crystal structure having a surface plane orientation within about 10 degrees of a 20 2̅3 or a 20 2̅3̅ crystallographic plane orientation and the axis of propagation extends in a high gain nonpolar direction. By forming cleaved facets that have an orientation corresponding to a nonpolar plane of the crystal structure of the substrate 10 in laser diodes with such substrate surface plane orientations, lasers with better performance, higher manufacturing yield, and lower laser cost (e.g., due to less poor quality facets) may be fabricated.

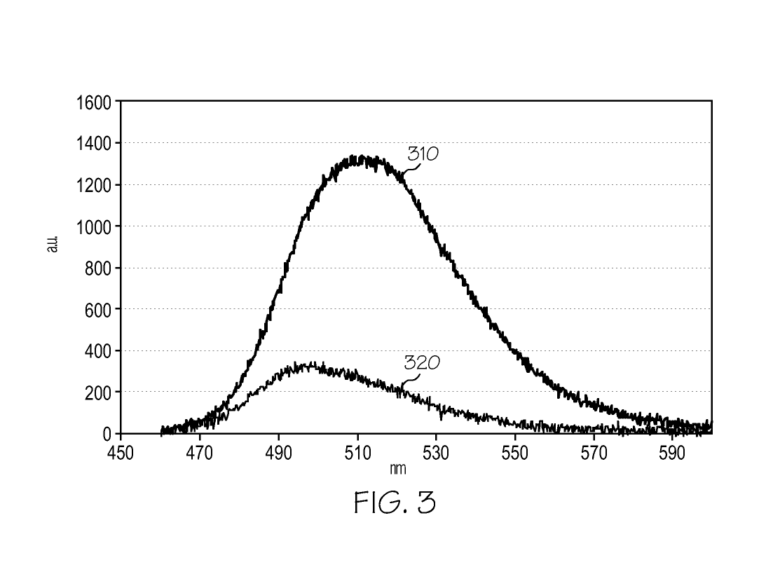

Experiments were conducted to verify that the DOG along the nonpolar direction was higher than the DOG in the projected c direction (and would thereby facilitate easy cleaving along a low index nonpolar plane perpendicular to the axis of propagation extending in the nonpolar direction) for laser diodes with substrates having a surface plane orientation within about 10 degrees of a 20 2̅3 or a 20 2̅3̅ crystallographic plane orientation. To verify that the DOG in the nonpolar direction was higher than the DOG in the projected c direction for light emitted in a nonpolar direction, the polarization-dependent photoluminescence was measured from the normal direction of the laser diode wafer for both the projected c direction E-vector component and the nonpolar E-vector component. When the measured photoluminescence E-vector is stronger in the projected c direction than in the nonpolar direction (e.g., by a factor of more than the square root of two), it can be concluded that the DOG is higher in the nonpolar direction. The results of these experiments are provided in the graphs of FIGS. 3-6 and show that the DOG is high in the nonpolar direction for laser diodes including substrates having surface plane orientations within about 10 degrees of a 20 2̅3 or a 20 2̅3̅ crystallographic plane orientation.

FIG. 3 depicts a graph of photoluminescence intensity with a projected c direction E-vector component 310 and a nonpolar E-vector component 320 as a function of wavelength for a laser diode emitting light in the green wavelength range at a high pump power density (e.g., >1 kW/cm² per quantum well, which is comparable with the pumping level during lasing). Because the measured photoluminescence intensity with the projected c direction E-vector component 310 is sufficiently higher than the measured photoluminescence intensity with the nonpolar E-vector component 320 for many wavelengths, the DOG is higher in the nonpolar direction than in the projected c direction for light emitted in the green wavelength range at a high pump power density.

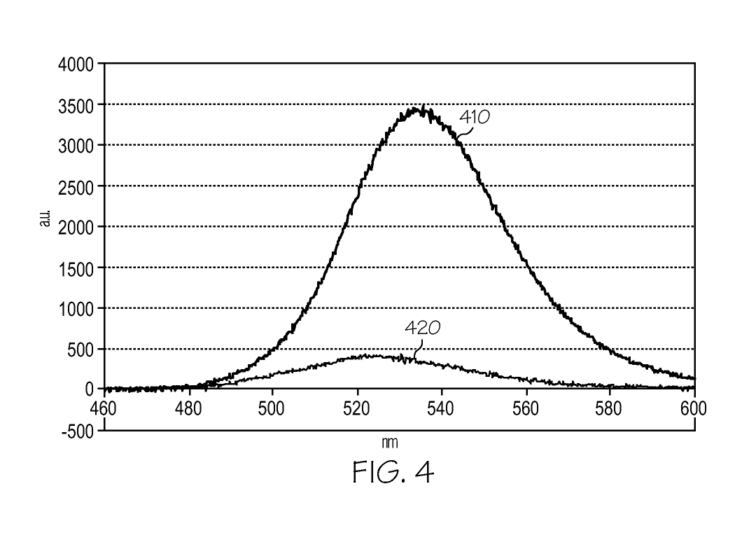

FIG. 4 depicts a graph of photoluminescence intensity with a projected c direction E-vector component 410 and a nonpolar E-vector component 420 as a function of wavelength for a laser diode emitting light in the green wavelength range at a low pump power density.

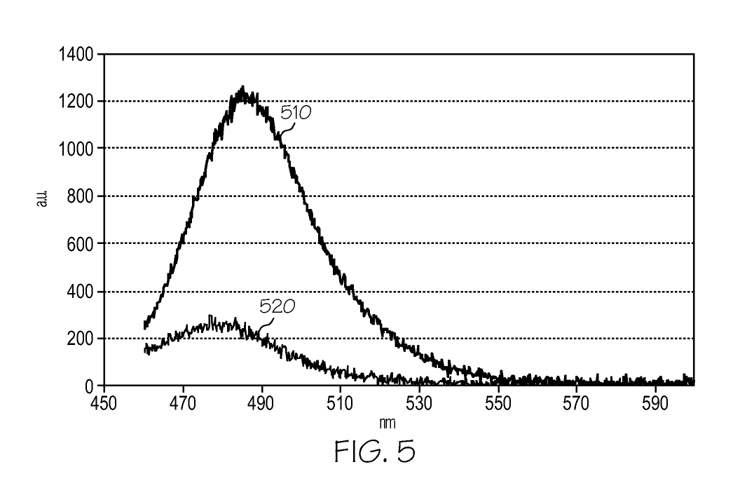

FIG. 5 is a graph of photoluminescence intensity with a projected c direction E-vector component 510 and a nonpolar E-vector component 520 as a function of wavelength for a laser diode emitting light in the blue-green wavelength range at a high pump power density. Because the measured photoluminescence intensity with the projected c direction E-vector component 510 is sufficiently higher than the measured photoluminescence intensity with the nonpolar E-vector component 520 for many wavelengths, the DOG is higher in the nonpolar direction than in the projected c direction for light emitted in the blue-green wavelength range at a high pump power density.

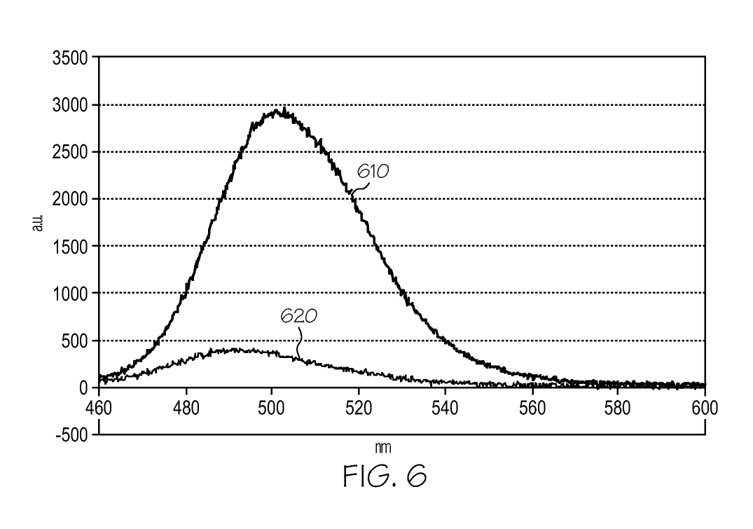

FIG. 6 is a graph of photoluminescence intensity with a projected c direction E-vector component 610 and a nonpolar E-vector component 620 as a function of wavelength for a laser diode emitting light in the blue-green wavelength range at a low pump power density.

When considered collectively, FIGS. 3-6 further demonstrate that the DOG is higher in the nonpolar direction than in the projected c direction for light emitted in the green and blue-green wavelength at both low pump power density and high pump power density for laser diodes including substrates having surface plane orientations within about 10 degrees of a 20 2̅3 or a 20 2̅3̅ crystallographic plane orientation.

In general, the laser diode 1 may be fabricated over a substrate such that the active region, the waveguide layers, and the cladding layers form a multilayered epitaxial structure that is subsequently cleaved to form cleaved facets. The layers of the laser diode 1 may be sequentially deposited to form the epitaxial structure, for example by any deposition technique known in the art or to be developed. As a non-limiting example techniques such as metalorganic chemical vapor deposition (MOCVD), metalorganic vapor phase epitaxy (MOVPE), and the like may be used. Metalorganic deposition processes may include precursors such as trimethyl gallium, trimethyl aluminum (TMA), trimethyl indium, and other compounds known in the art.

The grown epitaxial structure may include a substrate 10 comprising (Al,In)GaN, an n-side cladding layer 20 comprising (Al,In)GaN having an n-type conductivity, an n-side waveguide layer 60 comprising (Al,In)GaN having an n-type conductivity, an active region 40, a p-side waveguide layer 70 comprising (Al,In)GaN having a p-type conductivity, and a p-side cladding layer 30 comprising (Al,In)GaN having a p-type conductivity. The epitaxial structure may be fabricated such that: the active region 40 is interposed between the n-side cladding layer 20 and the p-side cladding layer 30 and extends substantially parallel to the n-side cladding layer 20 and the p-side cladding layer 30; the p-side waveguide layer 70 is interposed between the active region 40 and the p-side cladding layer 30; the n-side waveguide layer 60 is interposed between the active region 40 and the n-side cladding layer 20, the n-side cladding layer 20 is interposed between the n-side waveguide layer 60 and the substrate 10. The active region 40 includes one or more InGaN quantum wells producing electrically-pumped stimulated emission of photons the emission of which is guided along an axis of propagation by the n-side waveguide layer 60 and the p-side waveguide layer 70 and promoted by the n-side cladding layer 20 and the p-side cladding layer 30.

The epitaxial structure may be grown from a substrate with a crystal structure having a surface plane orientation within about 10 degrees of a 20 2̅3 or a 20 2̅3̅ crystallographic plane orientation. In one embodiment, the epitaxial structure may be grown from a substrate with a crystal structure having a surface plane orientation of about 20 2̅3. In another embodiment, the epitaxial structure may be grown from a substrate with a crystal structure having a surface plane orientation of about 20 2̅3̅.

Once the epitaxial structure is grown, it may be cleaved to form cleaved facets that form a laser cavity. The facets may be cleaved such that they have an orientation corresponding to a nonpolar plane of the crystal structure of the substrate.

In one embodiment, the axis of propagation of the fabricated laser diode extends in a direction within about 10 degrees of the <11 2̅0> direction with respect to the crystal structure of the substrate and the facets are cleaved to have an orientation corresponding to the 11 2̅0 plane of the crystal structure of the substrate.

It should now be understood that a laser diode having a substrate with a crystal structure having a surface plane orientation within about 10 degrees of a 20 2̅3 or a 20 2̅3̅ crystallographic plane orientation has high DOG and reduced QCSE for light propagating in a nonpolar direction, permitting the facets of the laser diode to be easily cleaved along a low index nonpolar plane.

It is noted that recitations herein of a component of the present disclosure being “configured” to embody a particular property, or to function in a particular manner, are structural recitations, as opposed to recitations of intended use. More specifically, the references herein to the manner in which a component is “configured” denotes an existing physical condition of the component and, as such, is to be taken as a definite recitation of the structural characteristics of the component.

As a matter of convenience only, device layers are referred to herein by terms such as “top” and “bottom.” Within the scope of any one embodiment, these terms are used to denote ordering of the device layers relative to a structure in which the substrate is regarded as the bottom of the device. Beyond this, the terms “top” and “bottom” are not intended to indicate any preferred orientation of the device during operation or fabrication. Accordingly, the term “above” means toward the structure top and the term “below” means toward the structure bottom.

It is noted that one or more of the following claims utilize the term “wherein” as a transitional phrase. For the purposes of defining the various embodiments of the present disclosure, it is noted that this term is introduced in the claims as an open-ended transitional phrase that is used to introduce a recitation of a series of characteristics of the structure and should be interpreted in like manner as the more commonly used open-ended preamble term “comprising.”

Unless otherwise defined, all technical and scientific terms used herein have the same meaning as commonly understood by one of ordinary skill in the art to which the subject matter of the present disclosure belongs. The terminology used in the description herein is for describing particular embodiments only and is not intended to be limiting. As used in the specification and appended claims, the singular forms “a,” “an,” and “the” are intended to include the plural forms as well, unless the context clearly indicates otherwise.

Unless otherwise indicated, all numbers expressing quantities of ingredients, properties such as molecular weight, reaction conditions, and so forth as used in the specification and claims are to be understood as being modified in all instances by the term “about.” Accordingly, unless otherwise indicated, the numerical properties set forth in the specification and claims are approximations that may vary depending on the desired properties sought to be obtained in embodiments of the present disclosure. Notwithstanding that the numerical ranges and parameters setting forth the broad scope of the various embodiments of the present disclosure are approximations, the numerical values set forth in the specific examples are reported as precisely as possible. One of ordinary skill in the art will understand that any numerical values inherently contain certain errors attributable to the measurement techniques used to ascertain the values.

What is claimed is:

1. A laser diode comprising a substrate comprising (Al,In)GaN, an n-side cladding layer comprising (Al,In)GaN having an n-type conductivity, an n-side waveguide layer comprising (Al,In)GaN having an n-type conductivity, an active region, a p-side waveguide layer comprising (Al,In)GaN having a p-type conductivity, a p-side cladding layer comprising (Al,In)GaN having a p-type conductivity, and a laser cavity formed by cleaved facets, wherein:
the active region is interposed between the n-side cladding layer and the p-side cladding layer and extends substantially parallel to the n-side cladding layer and the p-side cladding layer;
the p-side waveguide layer is interposed between the active region and the p-side cladding layer;
the n-side waveguide layer is interposed between the active region and the n-side cladding layer;
the n-side cladding layer is interposed between the n-side waveguide layer and the substrate;
the active region comprises one or more InGaN quantum wells producing electrically-pumped stimulated emission of photons, wherein the emission of photons is guided along an axis of propagation by the n-side waveguide layer and the p-side waveguide layer, and the propagation along the axis of propagation is promoted by the n-side cladding layer and the p-side cladding layer;
the substrate comprises a crystal structure having a surface plane orientation within about 10 degrees of a 20 2̅3 or a 20 2̅3̅ crystallographic plane orientation; and
the laser cavity is formed by cleaved facets that have an orientation corresponding to a nonpolar plane of the crystal structure of the substrate.

2. The laser diode of claim 1, wherein the substrate has a surface plane orientation of about 20 2̅3.

3. The laser diode of claim 1, wherein the substrate has a surface plane orientation of about 20 2̅3̅

4. The laser diode of claim 1, wherein the cleaved facets have an orientation corresponding to the 11 2̅0 plane of the crystal structure of the substrate.

5. The laser diode of claim 1, wherein the axis of propagation extends in a direction within about 10 degrees of the <11 2̅0> direction with respect to the crystal structure of the substrate.

6. The laser diode of claim 1 having an emission wavelength from about 470 nm to about 550 nm.

7. The laser diode of claim 1, wherein each InGaN quantum well is interposed between two (Al,In)GaN quantum well barriers.

8. The laser diode of claim 1, wherein each InGaN quantum well has a thickness from 1 nm to 10 nm.

9. The laser diode of claim 7, wherein each (Al,In)GaN quantum well barrier has a thickness from 1 nm to 30 nm.

10. The laser diode of claim 1, wherein the substrate is GaN with about a 20 2̅3 surface plane orientation.

11. The laser diode of claim 1, wherein the substrate is GaN with about a 20 2̅3̅ surface plane orientation.

12. The laser diode of claim 1, further comprising a ridge waveguide to optically guide the emitted photons.

13. The laser diode of claim 1, wherein the n-side cladding layer comprises AlInGaN having an n-type conductivity.

14. The laser diode of claim 1, wherein at least one of the n-side waveguide layer and the p-side waveguide layer comprises InGaN.

15. The laser diode of claim 1, wherein at least one of the n-side waveguide layer and the p-side cladding layer are partially or fully relaxed via formation of misfit dislocations positioned at least 20 nm from the InGaN quantum wells of the active region.

16. A method of fabricating a laser diode comprising:
growing an epitaxial structure comprising a substrate comprising (Al,In)GaN, an n-side cladding layer comprising (Al,In)GaN having an n-type conductivity, an n-side waveguide layer comprising (Al,In)GaN having an n-type conductivity, an active region, a p-side waveguide layer comprising (Al,In)GaN having a p-type conductivity, and a p-side cladding layer comprising (Al,In)GaN having a p-type conductivity wherein:
the active region is interposed between the n-side cladding layer and the p-side cladding layer and extends substantially parallel to the n-side cladding layer and the p-side cladding layer;
the p-side waveguide layer is interposed between the active region and the p-side cladding layer;
the n-side waveguide layer is interposed between the active region and the n-side cladding layer;
the n-side cladding layer is interposed between the n-side waveguide layer and the substrate;
the active region comprises one or more InGaN quantum wells producing electrically-pumped stimulated emission of photons, wherein the emission of photons is guided along an axis of propagation by the n-side waveguide layer and the p-side waveguide layer, and the propagation along the axis of propagation is promoted by the n-side cladding layer and the p-side cladding layer; and
the substrate comprises a crystal structure having a surface plane orientation within about 10 degrees of a 20 2̅3 or a 20 2̅3̅ crystallographic plane orientation; and
cleaving the epitaxial structure to form facets that form a laser cavity, wherein the facets have an orientation corresponding to a nonpolar plane of the crystal structure of the substrate.

17. The method of claim 16, wherein the substrate has a surface plane orientation of about 20 2̅3.

18. The method of claim 16, wherein the substrate has a surface plane orientation of about 20 2̅3̅.

19. The method of claim 16, wherein the axis of propagation extends in a direction within about 10 degrees of the <11 2̅0> direction with respect to the crystal structure of the substrate and the cleaved facets have an orientation corresponding to the 11 2̅0 plane of the crystal structure of the substrate.

20. The method of claim 19, further comprising forming a misfit dislocation in at least one of the n-side waveguide layer and the p-side cladding layer, wherein the misfit dislocation is formed at least 20 nm from an InGaN quantum well of the active region.
